(19) United States
(12) Patent Application Publication
(10) Pub. No.: US 2020/0084923 A1
(43) Pub. Date: Mar. 12, 2020

(54) ELECTROMAGNETIC WAVE SHIELDING FILM AND MANUFACTURING METHOD AND APPLICATION THEREOF

(71) Applicant: HENAN GUOAN ELECTRONIC MATERIAL CO., LTD., Jiaozuo, Henan (CN)

(72) Inventors: Qingchen CUI, Jiaozuo, Henan (CN); Guofa LI, Jiaozuo, Henan (CN); Wenjuan SONG, Jiaozuo, Henan (CN)

(21) Appl. No.: 16/490,764

(22) PCT Filed: Jun. 21, 2018
(86) PCT No.: PCT/CN2018/092150

§ 371 Date: Sep. 3, 2019

(30) Foreign Application Priority Data
Jan. 24, 2018 (CN) 201810069534.8

(51) Int. Cl. H05K 9/00; H05K 1/02

(52) U.S. Cl. CPC H05K 9/0084; H05K 2201/0715; H05K 1/0218

(57) ABSTRACT

The present invention provides an electromagnetic wave shielding film, comprising at least one electromagnetic shielding layer, one side of the electromagnetic shielding layer being an adhesive layer, and the other side an insulating layer. At least one side of the insulating layer is rough with a roughness of 2-10 μm. The thickness of the insulating layer is 1-10 μm. The thickness of the electromagnetic shielding layer is 10-5000 nm. The present invention also provides a method for preparing an electromagnetic wave shielding film, which includes roughening an insulating layer or adding inorganic particles to the material of the insulating layer to form an insulating layer with a roughened surface, forming an electromagnetic shielding layer on the roughened surface, and forming an adhesive layer on the surface of the electromagnetic shielding layer. The present invention significantly reduces the grounding resistance when the electromagnetic shielding film is applied.

### FIELD

The present invention belongs to the technical field of insulation, and particularly relates to an electromagnetic wave shielding film and a manufacturing method and application thereof.

### BACKGROUND

In recent years, as the demand of electromagnetic wave application is increased greatly, the research progress of the electromagnetic wave is gradually deepened, and the application band is developed more and more. In order to meet the needs of long-distance transmission and detection, the electromagnetic wave transmitting power of equipment such as radar, satellite communication and the like is also gradually increased, the electromagnetic wave intensity is greatly improved, and especially the electromagnetic wave intensity is greatly improved from the radio wave to a wide wave band of the microwave. At present, electromagnetic waves are generally applied to medical care, television broadcasting, mobile communication, and optical and other field, which provide many conveniences for life. However, a certain degree of electromagnetic wave pollution is caused by excessive application of electromagnetic waves, so that the electromagnetic environment of space background is increasingly complicated, and the requirements of anti-electromagnetic interference are provided in various fields. In recent years, the research on the optical technology continues to go deep. The application diversity of optical systems requires that electromagnetic waves that interfere with the system can be effectively shielded from the normal use, especially relates to the field of military, aerospace, and the like. The optical observation and detection equipment applied to various weapons and aircrafts has to meet the requirements of two aspects at the same time: on the one hand, the electromagnetic waves affecting the normal operation of the electronic components in the system and interference to the signal receiving equipment can be effectively shielded, and on the other hand, it needs to have excellent light transmission characteristics, so that the imaging quality of the optical system is not influenced to meet the requirements of equipment detection and observation. In order to solve the electromagnetic shielding problem, the electromagnetic shielding technology is researched and developed continuously.

The core of the shielding film for a circuit board is an electromagnetic shielding layer. A plurality of electromagnetic shielding films in various hierarchical forms is arranged around the electromagnetic shielding layer. CN103763893A discloses an electromagnetic wave shielding film and a printed circuit board comprising the shielding film, the manufacturing method comprises the following steps: hot-pressing and curing the electromagnetic shielding film and the circuit board in the thickness direction, and puncturing the bonding layer by using the rough surface of the electromagnetic shielding layer to realize grounding, or hot-pressing and curing the electromagnetic shielding film and the circuit board in the thickness direction, puncturing the shielding film by using a conductive material to achieve grounding, or hot-pressing and curing the electromagnetic shielding film and the circuit board in the thickness direction, forming a through hole or a blind hole in the circuit board. The hole is metallized to achieve grounding. The bonding layer of the shielding film in this invention does not contain conductive particles, so that reduces the cost, reduces the insertion loss, and satisfies the development demand of high-speed high-frequency of electronic products. However, the method adopted by the method for roughening the surface of the shielding layer is a copper foil roughening method for the circuit board, which needs to be subjected to roughening and then are cured, and then passivated, or a circuit board micro-etching method is adopted, and firstly roughening and then passivating are carried out. The reagents used in these roughening methods may pollute the environment, and some may even contain toxic substances. CN106061107A discloses a rigidity and flexibility combination circuit board possessing an electromagnetic shielding film and a manufacturing method thereof. The rigidity and flexibility combination circuit board possessing the electromagnetic shielding film comprises a rigid area and a flexible area. The rigid area comprises a first rigid daughter board, a bonding sheet, a flexible daughter board, the bonding sheet and a second rigid daughter board which are successively stacked. The flexible area comprises the electromagnetic shielding film, a cover film, a flexible daughter board, the covering film and the electromagnetic shielding film which are successively stacked. The electromagnetic shielding film comprises a first release film, an insulating layer and a conductive adhesive layer which are successively arranged in a laminated mode. According to the rigidity and flexibility combination circuit board possessing an electromagnetic shielding film, during a rigidity and flexibility combination plate manufacturing process, a lid is taken off and the flexible area is exposed, and then an auxiliary gasket which is designed specially is used so that the electromagnetic shielding film can be reliably pasted to a surface of the flexible area under effects of pressure and heat during a pressing process. However, the conductive adhesive layer of this invention is made of copper paste or silver paste, thus the cost is high. CN104883866A discloses an electromagnetic shielding film with excellent thermal conductivity and a manufacturing process of the electromagnetic shielding film. The electromagnetic shielding film comprises: a carrier film layer, a flexible ink layer, a thermal conductive ink layer and a conductive adhesive layer coated on the thermal conductive ink layer. The thermal conductive ink layer provides the electromagnetic shielding film with excellent thermal conductivity, and the heat conductivity coefficient can reach more than 2.0 W/m*k. The flexible ink layer provides the electromagnetic shielding film with excellent flexibility, so that the electromagnetic shielding film satisfies the use requirements of the flexible circuit board. The manufacturing process in this invention can be easily realized in the existing industrial production, and is convenient for industrial popularization and application. However, this invention has many layers of the shielding film, which increases the manufacturing cost.

At present, a conductive adhesive layer is contained in the basic structure of the shielding film, and the insertion loss of the circuit board can be increased by the conductive adhesive layer, the metal particles contained in the conductive adhesive layer can reduce the bending resistance of the circuit board. Therefore, in order to meet the demand, it is desirable to obtain an electromagnetic shielding film without the conductive adhesive layer by changing the formation method, material type and hierarchical structure of the electromagnetic shielding layer and the insulating layer to avoid insertion loss and reduction of bending resistance.

### SUMMARY

In order to solve the deficiencies of the prior art, it is an object of the present invention to provide an electromagnetic wave shielding film.

It is an additional object of the present invention to provide a method for manufacturing the above-described electromagnetic wave shielding film.

It is a further object of the present invention to provide an application of the above electromagnetic wave shielding film.

In order to achieve the above objectives, the present invention adopts the following technical solutions:

An electromagnetic wave shielding film comprises at least one electromagnetic shielding layer, and one side of the electromagnetic shielding layer is an adhesive layer, the other side is an insulating layer, and at least one side of the insulating layer is rough with a roughness of 2-10 μm, and preferably 1-8 μm.

Preferably, the material of the insulating layer is at least one of modified polyurethane, modified acrylate and modified epoxy insulating ink.

Preferably, the insulating layer has a thickness of 1-10 μm.

Preferably, the electromagnetic shielding layer has a thickness of 10-5000 nm.

Preferably, the electromagnetic shielding layer is a copper plated layer or a silver plated layer.

Preferably, the electromagnetic shielding layer is a copper plated layer of a metal material or a silver plated layer of a metal material.

Further preferably, the metal material is one of aluminum, titanium, zinc, iron, nickel, chromium, cobalt or copper elementary substance.

Further preferably, the metal material is an alloy formed of at least two of aluminum, titanium, zinc, iron, nickel, chromium, cobalt or copper elementary substance.

Preferably, the adhesive layer has a thickness of 1-15 μm.

Preferably, the material of the adhesive layer is at least one of modified epoxy resin, modified polyurethane and modified acrylate adhesive.

Preferably, the electromagnetic wave shielding film further comprises a base film and/or a protective film.

Preferably, the base film and/or the protective film are a non-silicon release material. Further preferably, the base film is a PET release film.

Still more preferably, the base film is a PET heavy release film.

A method for manufacturing an electromagnetic wave shielding film comprises the following steps:

(1) roughening an insulating layer or adding inorganic particles to the material of the insulating layer to form an insulating layer with a roughened surface;

(2) forming an electromagnetic shielding layer on the roughened surface treated in step (1); and

(3) forming an adhesive layer on the surface of the electromagnetic shielding layer formed in step (2).

Preferably, a method for manufacturing an electromagnetic wave shielding film comprises the following steps:

(1) coating on one side of a base film to form an insulating layer, roughening the insulating layer, or adding inorganic particles to the material of the insulating layer to form an insulating layer with a roughened surface;

(2) forming an electromagnetic shielding layer by vacuum evaporation or sputtering on the roughened surface treated in step (1);

(3) coating the surface of the electromagnetic shielding layer formed in step (2) to form an adhesive layer; and

(4) pasting a protective film on the surface of the adhesive layer formed in step (3).

The roughening treatment in step (1) is to coat the outer surface of the insulating layer with modified epoxy resin, modified polyurethane or modified acrylate adhesive containing inorganic particles.

Further preferably, the inorganic particles are at least one of silver powder, copper powder, nickel powder, aluminum hydroxide, aluminum oxide, titanium oxide and silicon dioxide.

Still more preferably, the inorganic particle has a diameter of 5-15 μm.

Further preferably, the coating method in steps (1) and (3) is at least one of extrusion coating, blade coating, dimple printing, roller printing and screen printing.

Further preferably, the protective film in step (4) is a PET film, a PEN film, and a PP film.

Further preferably, the protective film in step (4) is a release film or a micro-mucosa prepared by using a PET film, a PET film, a PEN film or a PP film as a substrate.

Further preferably, the protective film in step (4) is a micro-mucosa prepared by using a PET film, a PET film, a PEN film or a PP film as a substrate.

A circuit board comprises the electromagnetic wave shielding film of the above items.

### BENEFICIAL EFFECTS OF THE INVENTION

1. On the basis of the prior art, the present invention forms an insulating layer with a rough outer surface by coating a resin or an adhesive containing inorganic particles on the outer surface of the insulating layer or directly adding inorganic particles to the material of the insulating layer to achieve the purpose of roughening the junction surface between the insulating layer and the electromagnetic shielding layer, which significantly reduces the grounding resistance of the electromagnetic shielding film when applied.

2. The insulating layer of the present invention also achieves the conductive effect by the conductive paste, and the grounding resistance is significantly reduced, which is beneficial to reducing the electromagnetic interference of the circuit board, improving the signal transmission performance, and at the same time the heat resistance and peeling strength of the shielding film are not affected adversely, the bending resistance is significantly improved and the service life of the product is increased.

3. Compared with the prior art, the roughening treatment method provided by the present invention avoids the environmental pollution that may be caused by the reagent used in the conventional metal surface roughening process, and also avoids the use of the toxic reagent, and the operation process is simple.

### BRIEF DESCRIPTION OF THE DRAWINGS

FIG. 1 is a schematic view showing the structure of an electromagnetic shielding film formed by coating resin containing inorganic particles on the outer surface of an insulating layer.

FIG. 2 is a schematic view showing the structure of an electromagnetic shielding film formed by directly adding inorganic particles to the material of an insulating layer.

### DETAILED DESCRIPTION

The following examples are intended to further illustrate the present invention and are not intended to limit the scope of the present invention.

### EXAMPLE 1

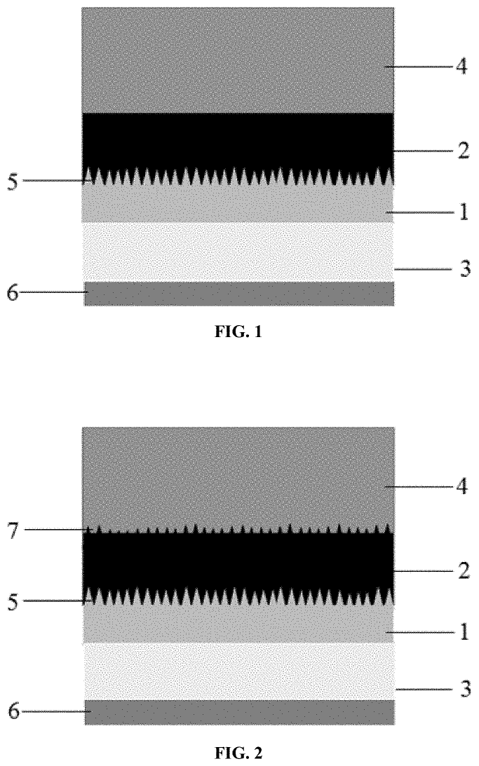

As shown in FIG. 1, an electromagnetic wave shielding film is provided. An insulating layer 2 is provided on a carrier film 4. An electromagnetic shielding layer 1 is provided on the insulating layer 2. An adhesive layer 3 is provided on the electromagnetic shielding layer 1. The carrier film is a PET film containing a non-silicon release material. A junction surface 5 between the electromagnetic shielding layer 1 and the insulating layer 2 is rough.

The method for manufacturing an electromagnetic wave shielding film comprises the following steps:

(1) selecting a PET heavy release film 4 with a thickness of 50 μm and a width of 250-1500 mm, coating an insulating layer material on the side of the release surface to form the insulating layer 2 with a thickness of 2 μm after being completely cured, coating modified epoxy resin containing inorganic particles on the insulating layer 2, and roughening the outer surface of the insulating layer, with a roughness of 2 to 10 μm after the roughening treatment;

(2) depositing an electromagnetic shielding layer material on the roughened surface treated in step (1) by vacuum evaporation to form the electromagnetic shielding layer 1 having a thickness of 100 nm;

(3) coating an adhesive layer material on the electromagnetic shielding layer formed in step (2) to form the adhesive layer 3 having a thickness of 2 μm; and

(4) pasting the protective film 6 on the surface of the adhesive layer formed in step (3).

The electromagnetic wave shielding film obtained as above is applied to a flexible circuit board.

### EXAMPLE 2

As shown in FIG. 2, an electromagnetic wave shielding film is provided. An insulating layer 2 is provided on a carrier film 4. An electromagnetic shielding layer 1 is provided on the insulating layer 2. A coating layer 3 is provided on the electromagnetic shielding layer 1. The outer surface of the coating layer is coated with a protective film 6. The insulating layer 2 contains inorganic particles having a particle diameter of 5-15 μm. A contact surface 7 between the insulating layer 2 and the carrier film 4 is not completely smooth. The contact surface 7 between the insulating layer 2 and the electromagnetic shielding layer 1 has a roughness of 2-10 μm. The carrier film 4 is a PET heavy release film.

The method for manufacturing an electromagnetic wave shielding film comprises the following steps:

(1) selecting a PET heavy release film with a thickness of 40 μm and a width of 250-1500 mm, coating an insulating layer material with inorganic particles on the side of the release surface to form the insulating layer 2 with a thickness of 10 μm after being completely cured, forming the rough surface 7 on the junction surface between the insulating layer and the carrier film 4 while coating the insulating layer 2, and the outer surface 5 of the insulating layer 2 (the junction surface between the insulating layer and the electromagnetic shielding layer 1) having a roughness of 2-10 μm;

(2) depositing an electromagnetic shielding layer material on the roughened surface treated in step (1) by sputtering to form an electromagnetic shielding layer 1 having a thickness of 500 nm;

(3) coating an adhesive layer material on the surface of the electromagnetic shielding layer 1 formed in step (2) to form the adhesive layer 3 having a thickness of 8 μm; and

(4) pasting a protective film 6 on the surface of the adhesive layer 3 formed in step (3).

The electromagnetic wave shielding film obtained as above is applied to a flexible circuit board.

### COMPARATIVE EXAMPLE 1

An electromagnetic wave shielding film is provided. An insulating layer is provided on a carrier film. An electromagnetic shielding layer is provided on the insulating layer. A coating layer is provided on the electromagnetic shielding layer. The carrier film is a PET heavy release film.

The method for manufacturing an electromagnetic wave shielding film comprises the following steps:

(1) selecting a PET heavy release film with a thickness of 75 μm and a width of 250-1500 mm, coating an insulating layer material on the side of the release surface to form an insulating layer with a thickness of 5 μm after being completely cured;

(2) depositing an electromagnetic shielding layer material on the roughened surface by vacuum evaporation on the surface of the insulating layer cured in step (1) to form an electromagnetic shielding layer having a thickness of 200 nm;

(3) directly coating a coating layer material on the surface of the electromagnetic shielding layer formed in step (2) to form an adhesive layer having a thickness of 10 μm; and

(4) pasting a protective film on the surface of the adhesive layer formed in step (3).

### COMPARATIVE EXAMPLE 2

An electromagnetic wave shielding film is provided. An insulating layer is provided on a carrier film. An electromagnetic shielding layer is provided on the insulating layer. An adhesive layer is provided on the electromagnetic shielding layer. The carrier film is a PET heavy release film.

The method for manufacturing an electromagnetic wave shielding film comprises the following steps:

(1) selecting a PET heavy release film with a thickness of 50 μm and a width of 250 to 1000 mm, coating an insulating layer material on the side of the release surface to form an insulating layer with a thickness of 10 μm after being completely cured;

(2) depositing an electromagnetic shielding layer material on the roughened surface by sputtering on the surface of the insulating layer cured in step (1) to form an electromagnetic shielding layer having a thickness of 300 nm;

(3) directly coating a coating layer material on the surface of the electromagnetic shielding layer formed in step (2) to form an adhesive layer having a thickness of 5 μm; and

(4) pasting a protective film on the surface of the adhesive layer formed in step (3).

The performance of the electromagnetic wave shielding films of the examples is compared with that of the comparative examples, and the results are shown in Table 1.

TABLE 1
Performance of electromagnetic wave shielding film

| Performance | | | COMPARATIVE | COMPARATIVE |
|---|---|---|---|---|
| Test | EXAMPLE 1 | EXAMPLE 2 | EXAMPLE 1 | EXAMPLE 2 |
| Grounding | 0.4 | 0.2 | 1.2 | 0.8 |
| Resistance (ohm) | | | | |
| Peeling | 1.1 | 1.3 | 1.4 | 1.0 |
| Strength | | | | |
| (Kgf/cm) | | | | |
| Heat | OK | OK | OK | OK |
| Resistance | | | | |
| (300° C., | | | | |
| wicking) | | | | |
| Bending | 15600 | 10800 | 8320 | 9350 |
| Resistance | | | | |
| (times) | | | | |

The roughness of the inter-layer junction surface has a significant effect on the grounding performance of the electromagnetic shielding film when the electromagnetic shielding film is applied. Examples 1-2 are compared to Comparative Examples 1-2, the grounding resistance of the interlayer junction surface after the roughening treatment is significantly lowered, which is due to the softening and flowing of the paste surface of the adhesive layer during the pressing process after the surface roughening treatment, and thus the electromagnetic shielding layer is brought into contact with the ground pad of the circuit board, which significantly reduces the grounding resistance. It is found that the optimal roughness of the surface roughening treatment of the insulating layer is 1-8 μm. If the roughness is too small, the requirement on the difference of the pressing segment is high, the contact is poor, and the grounding resistance is increased. If the roughness is too large, the adhesive layer will be unevenly coated.

The present invention adopts the insulating adhesive layer to achieve the conductive effect by the conductive paste, and the reduction of the grounding resistance is beneficial to reducing the electromagnetic interference of the circuit board and improving the signal transmission performance. There is no significant change in other properties, indicating that other properties are not adversely affected under the premise that the present invention guarantees the effects of electromagnetic shielding and good electrical conductivity (low grounding resistance). The bending resistance is significantly increased, which is beneficial to the prolonging of the service life of the product.

The above-described embodiments are preferred embodiments of the present invention, and the present invention can be implemented in other ways, and any obvious alternatives are within the scope of the present invention without departing from the inventive concept.

1. An electromagnetic wave shielding film, comprising at least one electromagnetic shielding layer, one side of the electromagnetic shielding layer is an adhesive layer, and the other side is an insulating layer, at least one side of the insulating layer is rough with a roughness of 2-10 μm.

2. The electromagnetic wave shielding film of claim 1, wherein the material of the insulating layer is at least one of modified polyurethane, modified acrylate or modified epoxy insulating ink.

3. The electromagnetic wave shielding film of claim 1, wherein the insulating layer has a thickness of 1-10 μm.

4. The electromagnetic wave shielding film of claim 1, wherein the electromagnetic shielding layer has a thickness of 10-5000 nm, and the electromagnetic shielding layer is a copper plated layer or a silver plated layer.

5. The electromagnetic wave shielding film of claim 1, wherein the adhesive layer has a thickness of 1-15 μm.

6. The electromagnetic wave shielding film of claim 1, wherein the material of the adhesive layer is at least one of modified epoxy resin, modified polyurethane and modified acrylate adhesive.

7. The electromagnetic wave shielding film of claim 1, wherein the electromagnetic wave shielding film further comprises a base film and/or a protective film.

8. A method for manufacturing an electromagnetic wave shielding film of claim 1, comprising steps of:
(1) roughening an insulating layer or adding inorganic particles to the material of the insulating layer to form an insulating layer with a roughened surface;
(2) forming an electromagnetic shielding layer on the roughened surface treated in step (1); and
(3) forming an adhesive layer on the surface of the electromagnetic shielding layer formed in step (2).

9. The method for manufacturing an electromagnetic wave shielding film of claim 8, wherein the printing roughening treatment in step (1) is to coat the outer surface of the insulating layer with modified epoxy resin, modified polyurethane or modified acrylate adhesive containing inorganic particles.

10. A circuit board comprising an electromagnetic wave shielding film of claim 1.

11. A method for manufacturing an electromagnetic wave shielding film of claim 2, comprising steps of:
(1) roughening an insulating layer or adding inorganic particles to the material of the insulating layer to form an insulating layer with a roughened surface;
(2) forming an electromagnetic shielding layer on the roughened surface treated in step (1); and
(3) forming an adhesive layer on the surface of the electromagnetic shielding layer formed in step (2).

12. A method for manufacturing an electromagnetic wave shielding film of claim 3, comprising steps of:
(1) roughening an insulating layer or adding inorganic particles to the material of the insulating layer to form an insulating layer with a roughened surface;
(2) forming an electromagnetic shielding layer on the roughened surface treated in step (1); and
(3) forming an adhesive layer on the surface of the electromagnetic shielding layer formed in step (2).

13. A method for manufacturing an electromagnetic wave shielding film of claim 4, comprising steps of:
(1) roughening an insulating layer or adding inorganic particles to the material of the insulating layer to form an insulating layer with a roughened surface;
(2) forming an electromagnetic shielding layer on the roughened surface treated in step (1); and
(3) forming an adhesive layer on the surface of the electromagnetic shielding layer formed in step (2).

14. A method for manufacturing an electromagnetic wave shielding film of claim 5, comprising steps of:
(1) roughening an insulating layer or adding inorganic particles to the material of the insulating layer to form an insulating layer with a roughened surface;
(2) forming an electromagnetic shielding layer on the roughened surface treated in step (1); and
(3) forming an adhesive layer on the surface of the electromagnetic shielding layer formed in step (2).

15. A method for manufacturing an electromagnetic wave shielding film of claim 6, comprising steps of:
(1) roughening an insulating layer or adding inorganic particles to the material of the insulating layer to form an insulating layer with a roughened surface;
(2) forming an electromagnetic shielding layer on the roughened surface treated in step (1); and
(3) forming an adhesive layer on the surface of the electromagnetic shielding layer formed in step (2).

16. A method for manufacturing an electromagnetic wave shielding film of claim 7, comprising steps of:
(1) roughening an insulating layer or adding inorganic particles to the material of the insulating layer to form an insulating layer with a roughened surface;
(2) forming an electromagnetic shielding layer on the roughened surface treated in step (1); and
(3) forming an adhesive layer on the surface of the electromagnetic shielding layer formed in step (2).

17. A circuit board comprising an electromagnetic wave shielding film of claim 2.

18. A circuit board comprising an electromagnetic wave shielding film of claim 3.

19. A circuit board comprising an electromagnetic wave shielding film of claim 4.

20. A circuit board comprising an electromagnetic wave shielding film of claim 5.

21. A circuit board comprising an electromagnetic wave shielding film of claim 6.

22. A circuit board comprising an electromagnetic wave shielding film of claim 7.
